(19) United States
(12) Patent Application Publication
(10) Pub. No.: US 2026/0076106 A1
(43) Pub. Date: Mar. 12, 2026

(54) Semiconductor structure including resistive random access memory and double capacitor and manufacturing method thereof

(71) Applicant: UNITED MICROELECTRONICS CORP., Hsin-Chu City (TW)

(72) Inventors: Da-Jun Lin, Kaohsiung City (TW); Tai-Cheng Hou, Tainan City (TW); Fu-Yu Tsai, Tainan City (TW); Bin-Siang Tsai, Changhua County (TW)

(73) Assignee: UNITED MICROELECTRONICS CORP., Hsin-Chu City (TW)

(21) Appl. No.: 18/912,538

(22) Filed: Oct. 10, 2024

(30) Foreign Application Priority Data
Sep. 6, 2024 (TW) 113133865

(51) Int. Cl. H10N 70/00; H01L 23/522; H10B 63/00

(52) U.S. Cl. CPC H10N 70/8833; H10B 63/80; H10D 1/696; H10N 70/063; H10N 70/841; H10W 20/496

(57) ABSTRACT

The invention provides a semiconductor structure comprising a resistive random access memory (RRAM) and a double capacitor. The semiconductor structure includes a substrate, wherein a cell region and a capacitor region are defined on the substrate, and the resistive random access memory is located in the cell region, wherein the RRAM comprises a variable resistance layer, and a double capacitor structure is located in the capacitor region, wherein the double capacitor structure comprises a lower capacitor structure and an upper capacitor structure, and the material of a first high dielectric constant layer in the lower capacitor structure is the same as the material of the variable resistance layer.

### BACKGROUND OF THE INVENTION

### 1. Field of the Invention

The invention relates to the field of semiconductors, in particular to a semiconductor structure integrating a resistive random access memory and a double capacitor structure and a manufacturing method thereof.

### 2. Description of the Prior Art

Resistive random access memory (RRAM) has the advantages of simple structure, low operating voltage, high operating speed, good durability and compatibility with CMOS process. RRAM is the most promising substitute for traditional flash memory, so as to achieve the purpose of reducing the device size. RRAM is being widely used in various components such as optical disks and nonvolatile memory arrays.

RRAM cells store data in a material layer that can be induced to change phase. In all or part of the layers, the material can induce a phase change and switch between a high-resistance state and a low-resistance state. After different resistance states are detected, they can be expressed as “0” or “1”. In a typical RRAM cell, the data storage layer consists of amorphous metal oxide. After applying enough voltage, the voltage can form a metal bridge across the data storage layer, thus forming a low resistance state. Then, all or part of the metal structure can be decomposed or melted by applying pulses with high current density or in other ways, so that the metal bridge is broken and the high resistance state is restored. Then when the data storage layer cools rapidly, it will change from high resistance state to low resistance state again.

With the area of semiconductor devices getting smaller and smaller, various devices with different functions are often combined on the same substrate to improve the density of devices. In this process, how to effectively integrate various components is one of the research directions in this field.

### SUMMARY OF THE INVENTION

The invention provides a semiconductor structure comprising a resistive random access memory (RRAM) and a double capacitor, which comprises a substrate, a cell region and a capacitor region are defined thereon, and the capacitor region is located beside the cell region, a resistive random access memory located in the cell region, wherein the resistive random access memory includes a variable resistance layer, and a double capacitor structure located in the capacitor region, wherein the double capacitor structure comprises a lower capacitor structure and an upper capacitor structure, and the material of a first high dielectric constant layer in the lower capacitor structure is the same as the material of the variable resistance layer of the resistive random access memory

The invention also provides a method for manufacturing a semiconductor structure comprising a resistive random access memory (RRAM) and a double capacitor, which comprises the following steps: providing a substrate, wherein a cell region and a capacitor region are defined on the substrate and located beside the cell region, forming a resistive random access memory located in the cell region, wherein the resistive random access memory comprises a variable resistance layer, and forming a double capacitor structure in the capacitor region, wherein the double capacitor structure comprises a lower capacitor structure and an upper capacitor structure, and the material of a first high dielectric constant layer in the lower capacitor structure is the same as the material of the variable resistance layer of the resistive random access memory.

The invention provides a semiconductor structure integrated with RRAM and double capacitor and a manufacturing method thereof. In which double capacitor structure is formed in the process of manufacturing RRAM, so the process steps can be saved. In addition, a contact structure can be formed at the same time in the manufacturing process to electrically connect the bottom electrode of RRAM and the bottom electrode of the double capacitor structure, so it is unnecessary to form another contact to connect the bottom electrode of the double capacitor structure in the subsequent process, which can further save the manufacturing steps. The invention effectively integrates RRAM and double capacitor under the existing manufacturing process, and provides a semiconductor integrated structure with stable structure and simple manufacturing process and a manufacturing method thereof.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIGS. 1 to 7 are schematic cross-sectional views of a semiconductor structure integrated with a resistive random access memory and a double capacitor structure according to an embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

As mentioned in the prior art, with the development of semiconductor technology, in order to reduce the space of components and reduce the process cost, we can try to integrate a variety of different components on the same substrate. In the next semiconductor structure of the present invention, a resistive random access memory (RRAM) and a double capacitor structure are integrated, which will be described in detail in the following paragraphs.

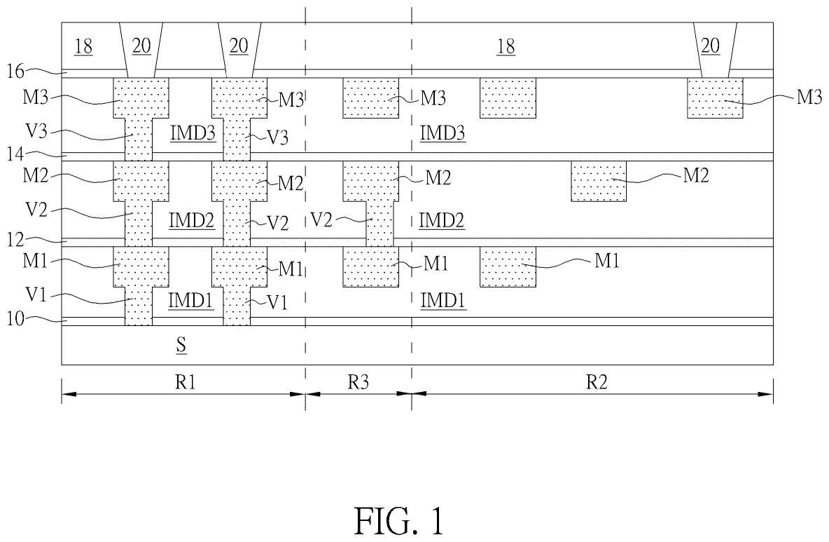

Please refer to FIGS. 1 to 7. FIGS. 1 to 7 are schematic cross-sectional views of a semiconductor structure integrated with a resistive random access memory (RRAM) and a double capacitor structure according to an embodiment of the present invention. As shown in FIG. 1, firstly, a substrate S is provided, such as a silicon substrate or a material layer containing electronic components (such as transistors). A multi-layer structure is sequentially formed on the substrate S. Taking FIG. 1 as an example, it includes a mask layer 10, a first dielectric layer IMD1, a mask layer 12, a second dielectric layer IMD2, a mask layer 14, a third dielectric layer IMD3, a mask layer 16 and a fourth dielectric layer 18. The materials of the first dielectric layer IMD1, the second dielectric layer IMD2, the third dielectric layer IMD3 and the fourth dielectric layer 18 are, for example, silicon oxide, while the materials of the mask layer 10, the mask layer 12, the mask layer 14 and the mask layer 16 are, for example, silicon nitride or silicon oxynitride, but the present invention is not limited to this. In addition, the number of mask layers and dielectric layers shown in FIG. 1 can also be adjusted according to actual needs. In other words, in other embodiments of the present invention, the semiconductor structure may also include more or less mask layers and dielectric layers, and this variable structure is also within the scope of the present invention.

The mask layer 10 and the first dielectric layer IMD1 contain conductive vias V1 and the first metal layer M1, the mask layer 12 and the second dielectric layer IMD2 contain conductive vias V2 and the second metal layer M2, the mask layer 14 and the third dielectric layer IMD3 contain conductive vias V3 and the third metal layer M3, and the mask layer 16 and the fourth dielectric layer 18 contain conductive vias 20. Here, the conductive vias V1, V2, V3, 20 and the first metal layer M1, the second metal layer M2, and the third metal layer M3 are made of materials with good conductivity, such as tungsten, cobalt, copper, aluminum, gold, silver, etc., wherein the first metal layer M1, the second metal layer M2, and the third metal layer M3 are mainly used for electrically connecting various components in the horizontal direction, that is, electrically connecting various electronic components in the same layer structure. And the main functions of the conductive vias V1, V2, V3 and 20 are to connect electronic components in vertical directions (that is, different layers). The technology of metal layer and conductive via belongs to the known technology in this field, therefore, these technologies are not detailed here

In addition, the semiconductor device in FIG. 1 also includes a cell region R1, a capacitor region R2 and a logic region R3, wherein the cell region R1, the capacitor region R2 and the logic region R3 are distributed on the substrate S. In the following steps, devices such as RRAM will be formed in the cell region R1, a double capacitor structure will be formed in the capacitor region R2 for storing charges, and logic circuits and various electronic devices will be formed in the logic region R3. In this embodiment, although the logic region R3 is arranged between the cell region R1 and the capacitor region R2, the present invention is not limited to this arrangement, that is, the positions of the three regions can be adjusted as required. In addition, in this embodiment, the junction between the cell region R1 and the logic region R3, and the junction between the capacitor region R2 and the logic region R3 are indicated by dashed lines, where the dashed lines may represent that the two regions are directly adjacent to each other, or in other embodiments, they may also represent that the two regions are not directly adjacent to each other (that is, there may be other elements such as blank regions disposed between the two regions), and the above changes are within the scope of the present invention.

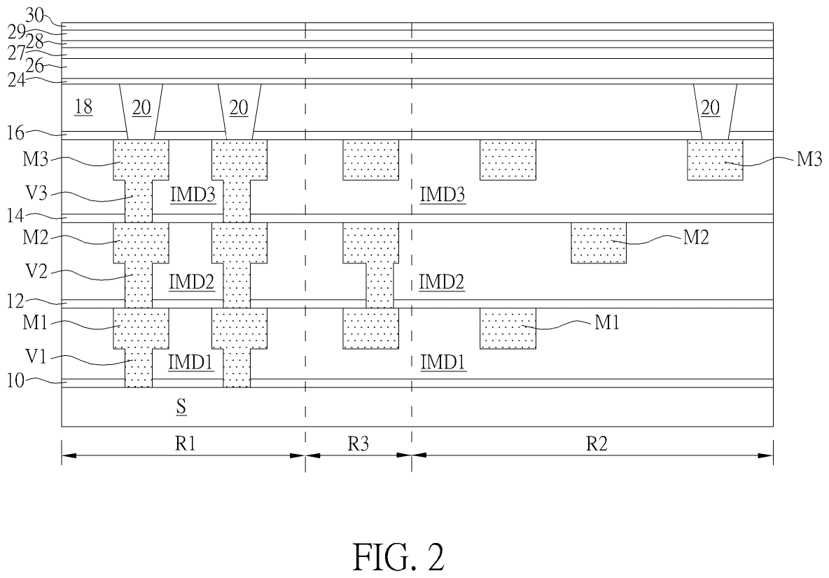

As shown in FIG. 2, a first electrode layer 24, a first high dielectric constant layer 26, a barrier layer 27, a second electrode layer 28, a second high dielectric constant layer 29 and a third electrode layer 30 are sequentially formed in the cell region R1, the capacitor region R2 and the logic region R3, wherein the materials of the first electrode layer 24, the second electrode layer 28 and the third electrode layer 30 are, for example, titanium, titanium nitride, tantalum or tantalum nitride, but not limited thereto. The first electrode layer 24, the second electrode layer 28, and the third electrode layer 30 are used as the electrode plates of the subsequently formed resistive random access memory (RRAM) and the double capacitor structure. In more detail, the first electrode layer 24 and the second electrode layer 28 can be used as the lower electrode and the upper electrode of RRAM, while the first electrode layer 24, the second electrode layer 28 and the third electrode layer 30 can be used as the bottom electrode, the middle electrode and the upper electrode of the subsequently formed double capacitor structure, respectively.

The first high dielectric constant layer 26 is formed between the first electrode layer 24 and the barrier layer 27. In the following steps, the first high dielectric constant layer 26 located in the cell region R1 will be used as the variable resistance layer of RRAM, and at the same time, because the first high dielectric constant layer 26 is also formed in the capacitor region R2, the first high dielectric constant layer 26 located in the capacitor region R2 can also be used as the insulating layer of the lower capacitor structure of the double capacitor structure. In this embodiment, tantalum oxide (TaOx) is selected as the material of the first high dielectric constant layer 26, but the present invention is not limited to this.

The barrier layer 27 is made of, for example, ruthenium (Ru), platinum (Pt) or iridium (Ir), which is less likely to react with other substances in the process, so it can be used as an etching stop layer in the process. In addition, due to the migration of oxygen vacancies during RRAM driving, the barrier layer 27 is arranged above the first high dielectric constant layer 26, which can also prevent oxygen ions from migrating to the top and reacting with metals. In addition, in the present invention, oxides of the above metals, such as ruthenium oxide, platinum oxide, iridium oxide, etc., can also be used as the material of the barrier layer 27, which is also within the scope of the present invention.

The material of the second high dielectric constant layer 29, such as a suitable high dielectric constant layer, can be used as the insulating layer of the upper capacitor structure in the double capacitor structure. More specifically, in this embodiment, the second high dielectric constant layer 29 comprises a stacked structure of zirconia, alumina and zirconia (also called ZAZ). Zirconia has a high dielectric constant, but its leakage current is large when it is used as the insulating layer of capacitor, so adding alumina can reduce the leakage current of the whole stacked material. It can be understood that the first high dielectric constant layer 26 and the second high dielectric constant layer 29 of the present invention can also contain other suitable high dielectric constant materials, such as hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta2O₉, SBT), lead zirconate titanate (PbZrxTi₁-xO₃, PZT), barium strontium titanate (BaxSr₁-xTiO₃, BST) or a combination thereof. But the present invention is not limited thereto.

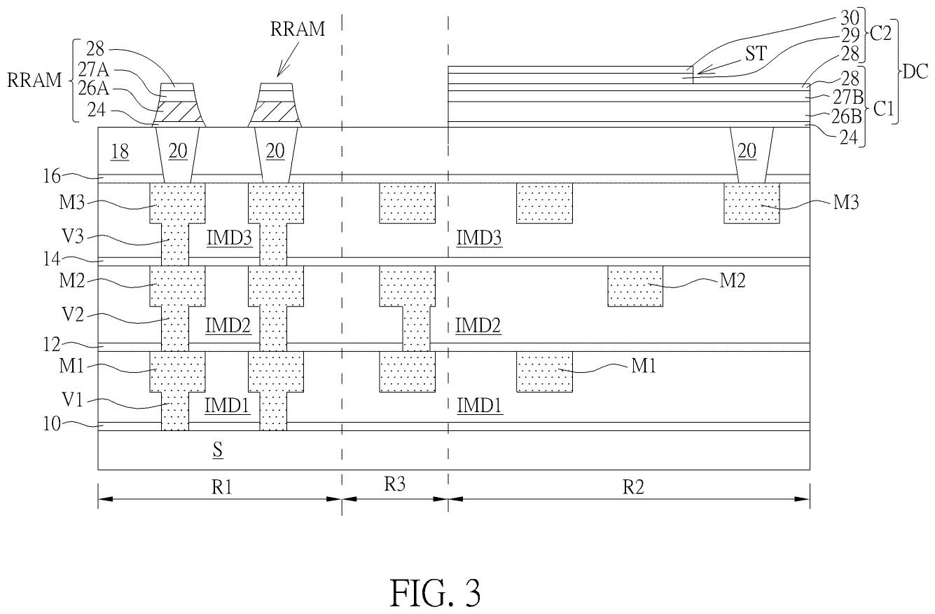

As shown in FIG. 3, one or more patterning steps are performed to form a pattern of RRAM in the cell region R1 and a double capacitor structure in the capacitor region R2. More specifically, in FIG. 3, after the patterning step, the patterned first electrode layer 24, the first high dielectric constant layer 26, the barrier layer 27 and the second electrode layer 28 are left in the cell region R1. These material layers together form the RRAM structure. As mentioned above, the first electrode layer 24 and the second electrode layer 28 are respectively used as the lower electrode and the upper electrode of the RRAM, while the first high dielectric constant layer 26 is used as the variable resistance layer of the RRAM. For convenience of distinction, the first high dielectric constant layer 26 located in the cell region R1 is defined as the variable resistance layer 26A. It can be understood that the variable resistance layer 26A is a part of the RRAM, and its material is the same as the above-mentioned first high dielectric constant layer 26.

Referring also to FIG. 3, after the patterning step, the patterned first electrode layer 24, first high dielectric constant layer 26, barrier layer 27, second electrode layer 28, second high dielectric constant layer 29 and third electrode layer 30 are left in the capacitor region R2, and these material layers form a double capacitor structure DC. More specifically, the double capacitor structure DC includes a lower capacitor structure C1 and an upper capacitor structure C2, wherein the lower capacitor structure C1 includes a first electrode layer 24 as a lower electrode, a first high dielectric constant layer 26 as an insulating layer, and a barrier layer 27 and a second electrode layer 28 as an upper electrode. The upper capacitor structure C2 includes a second electrode layer 28 as a lower electrode, a second high dielectric constant layer 29 as an insulating layer, and a third electrode layer 30 as an upper electrode. It is worth noting that the insulating layer in the lower capacitor structure C1 is formed at the same time as the variable resistance layer 26A in the RRAM, and the material is the same. Here, for convenience of distinction, the insulating layer in the lower capacitor structure C1 is defined as the first insulating layer 26B. In addition, in order to facilitate the subsequent connection of the wires to the electrodes, it is preferable to design the area of the upper capacitor structure C2 to be smaller than that of the lower capacitor structure C1, that is, to remove part of the second high dielectric constant layer 29 and the third electrode layer 30, so that the top surface of the second electrode layer 28 is partially exposed, and a stepped profile ST is formed in cross section.

Similarly, except for the first high dielectric constant layer 26, the first electrode layer 24, the barrier layer 27 and the second electrode layer 28 are all formed in the cell region R1 and the capacitor region R2, respectively, and the material layers located in the cell region R1 constitute a part of the RRAM, while the material layers located in the capacitor region R2 constitute a part of the double capacitor structure DC. Here, for convenience of distinction, the barrier layer 27 located in the cell region R1 is defined as the first barrier layer 27A, while the barrier layer 27 located in the capacitor region R2 is defined as the second barrier layer 27B.

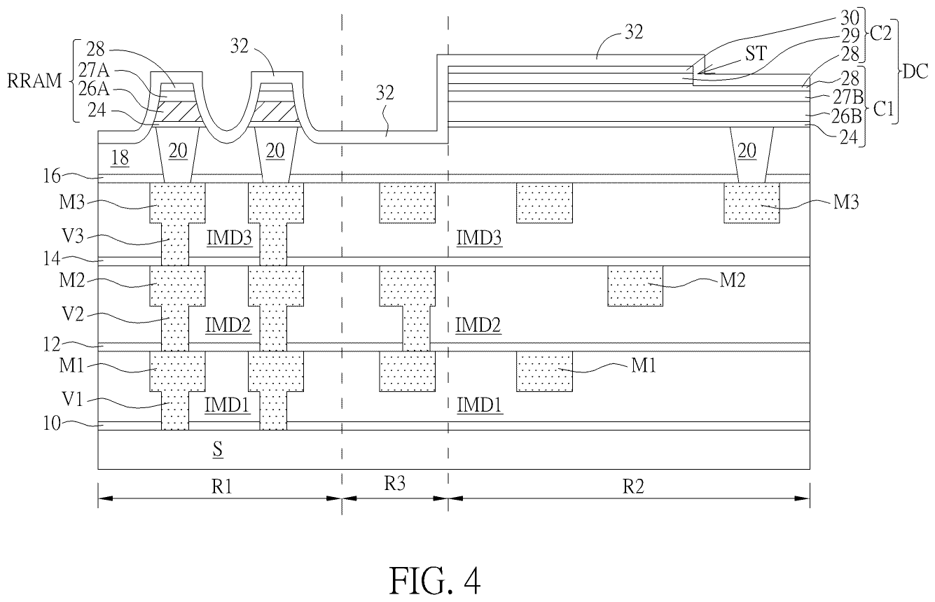

As shown in FIG. 4, a nitride layer 32 is continuously formed in the cell region R1, the capacitor region R2 and the logic region R3, and the nitride layer 32 covers each RRAM and the double capacitor structure DC. In this embodiment, the material of the nitride layer 32 includes silicon nitride. The nitride layer 32 can be used to protect the RRAM and the double capacitor structure DC.

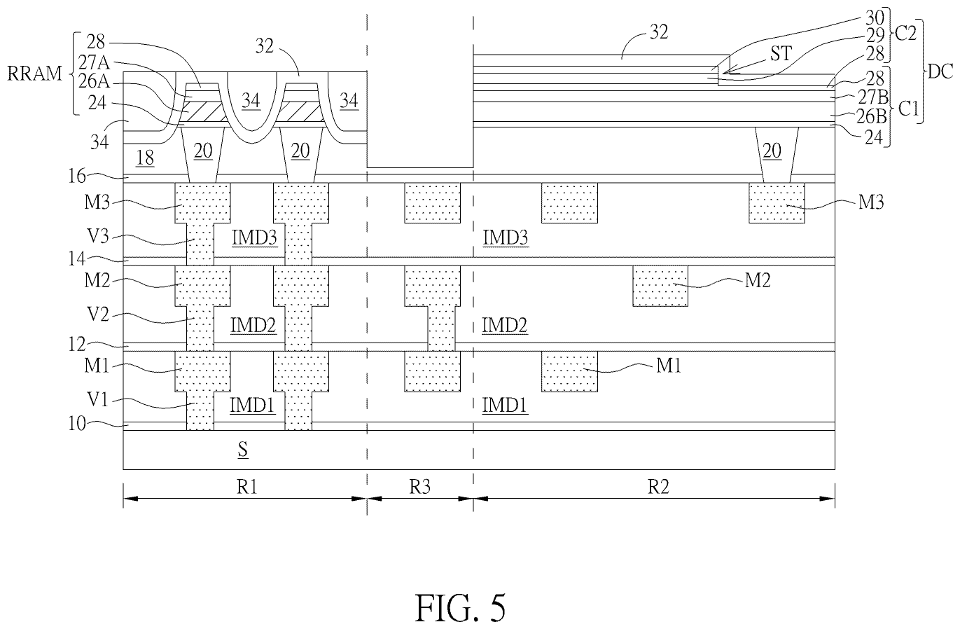

As shown in FIG. 5, an oxide layer 34 is then formed to fill the gaps between the RRAMs, where the oxide layer 34 can be performed by atomic layer deposition (ALD) because the gap size between RRAMs is small, but the present invention is not limited to this. Subsequently, the excess oxide layer 34 and nitride layer 32 are removed by etching back. For example, the nitride layer 32 in the logic region R3 is also completely removed.

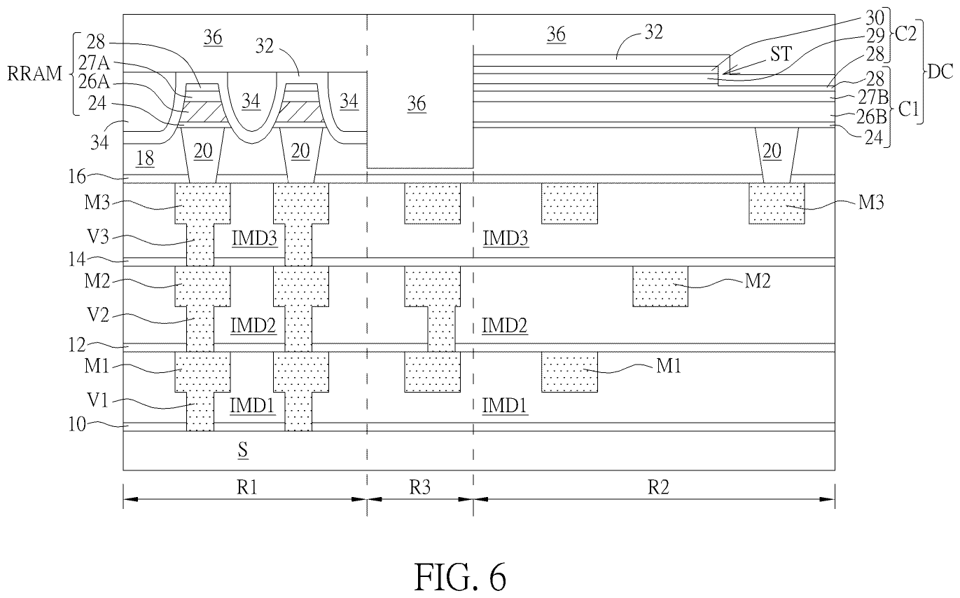

As shown in FIG. 6, a dielectric layer 36 is formed in the cell region R1, the capacitor region R2 and the logic region R3, and the dielectric layer 36 comprises an ultra-low dielectric constant material (ULK), such as silicon oxycarbide (SiCOH) or organosilicate glass (OSG), but the present invention is not limited to this. After the dielectric layer 36 covers the RRAM in the cell region R1 and the double capacitor structures (C1, C2) in the capacitor region R2, a planarization step, such as chemical mechanical polishing, is performed to make the top surfaces of the dielectric layers 36 in the cell region R1, the capacitor region R2 and the logic region R3 flush.

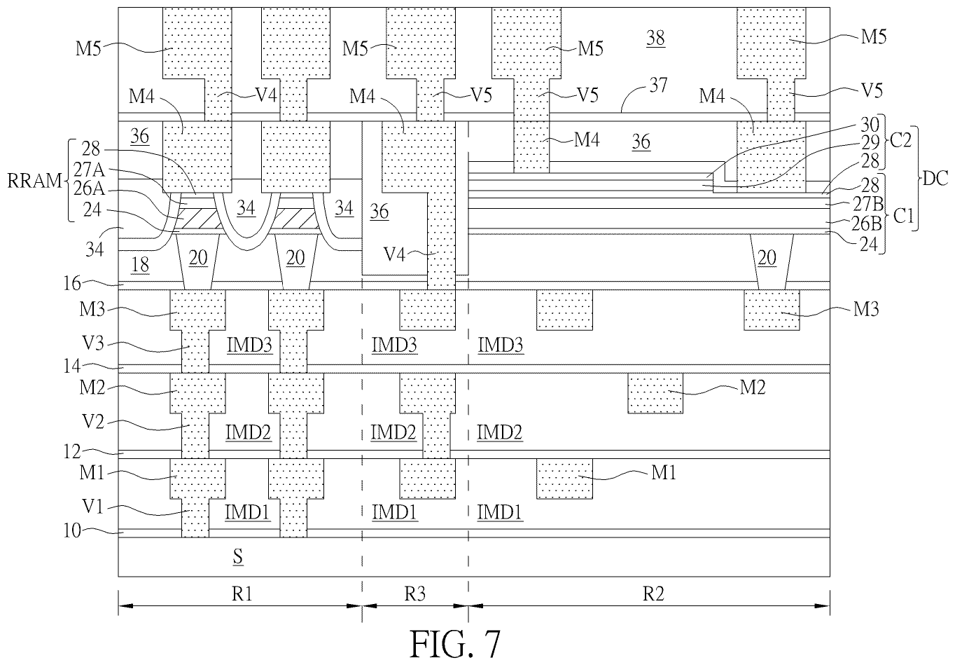

As shown in FIG. 7, a mask layer 37 and a dielectric layer 38 are continuously formed on the surface of the dielectric layer 36, and then a plurality of fourth metal layers M4, conductive vias V4, fifth metal layers M5 and conductive vias V5 are formed in the cell region R1, the capacitor region R2 and the logic region R3. The fourth metal layer M4 in the cell region R1 is electrically connected to the second electrode layer (i.e., the top electrode of RRAM) 28 of RRAM. In the capacitor region R2, the fourth metal layer M4 is electrically connected to the second electrode layer 28 (i.e., the top electrode of the lower capacitor structure C1 or the bottom electrode of the upper capacitor structure C2). As for the upper electrode (third electrode layer 30) of the upper capacitor structure C2 in the capacitor region R2 is connected to the conductive via V5, while the lower electrode (first electrode layer 24) of the lower capacitor structure C1 in the capacitor region R2 is connected to the conductive via 20 that has been formed previously. The wire structure in the logic region R3 is connected to other circuit elements through the fourth metal layer M4, the conductive via V4, the fifth metal layer M5 and the conductive via V5. So far, the semiconductor structure integrating RRAM and double capacitor provided by the present invention has been completed.

As shown in FIG. 7, one of the characteristics of the present invention is that the first electrode layer 24, the first high dielectric constant layer 26, the barrier layer 27, and the second electrode layer 28 are simultaneously formed in the cell region R1 and the capacitor region R2. After the patterning step, these material layers constitute RRAM in the cell region R1 and also constitute the lower capacitor structure C1 in the capacitor region R2. Therefore, the components in the two regions share a part of the material layer, which can effectively reduce the process steps and achieve the purpose of improving the production efficiency.

Another feature of the present invention is that when the conductive vias 20 for electrically connecting RRAM are formed, a part of the conductive vias 20 are also located in the capacitor region R2 (as shown in FIG. 1), and these conductive vias 20 formed in the capacitor region R2 can be directly electrically connected to the bottom electrode (i.e., the first electrode layer 24) of the lower capacitor structure C1 formed subsequently. Therefore, when the structures such as the fourth metal layer M4, the conductive vias V4 and the fifth metal layer M5 are formed in the subsequent steps to connect the upper electrode and the middle electrode of the double capacitor structure, it is not necessary to penetrate the electrode structure from above to connect to the bottom electrode, thus simplifying the manufacturing process and improving the stability of the product.

The invention provides a semiconductor structure integrating RRAM and double capacitor structure. The double capacitor structure DC is connected in parallel by the lower capacitor structure C1 and the upper capacitor structure C2, and the double capacitor structure can store more charges than the single capacitor. In other embodiments of the present invention, it is also possible to form more capacitor structures, for example, three, four or more capacitors are connected in parallel to each other, so as to further increase the stored charge. This variation is also within the scope of the present invention.

Based on the above description and drawings, the present invention provides a semiconductor structure including a resistive random access memory (RRAM) and a double capacitor DC, including a substrate S, on which a cell region R1 and a capacitor region R2 are defined, and a resistive random access memory RRAM is located in the cell region R1, wherein the resistive random access memory RRAM includes a variable resistance layer 26A, and a double capacitor structure DC located in the capacitor region R2, wherein the double capacitor structure DC comprises a lower capacitor structure C1 and an upper capacitor structure C2, and the material of a first high dielectric constant layer 26B in the lower capacitor structure C1 is the same as that of the variable resistance layer 26A of the resistive random access memory RRAM.

In some embodiments of the present invention, the double capacitor structure comprises a lower electrode (first electrode layer 24), a first high dielectric constant layer 26, a middle electrode (second electrode layer 28), a second high dielectric constant layer 29 and an upper electrode (third electrode layer 30) in order from bottom to top, wherein the lower electrode 24, the first high dielectric constant layer 26 and the middle electrode 28 constitute the lower capacitor structure C1, and the middle electrode 28, the second high dielectric constant layer 29 and the upper electrode 30 constitute the upper capacitor structure C2.

In some embodiments of the present invention, it further includes a first barrier layer 27A located on the variable resistance layer 26A in the resistive random access memory RRAM, and a second barrier layer 27B located between the first high dielectric constant layer 26 and the middle electrode 28 in the dual capacitance structure DC.

In some embodiments of the present invention, the materials of the first barrier layer 27A and the second barrier layer 27B are the same, and the materials of the first barrier layer 27A and the second barrier layer 27B include ruthenium, iridium or platinum.

In some embodiments of the present invention, the material of the second high dielectric constant layer 29 comprises a stacked layer of zirconium dioxide and aluminum oxide (ZAZ).

In some embodiments of the present invention, it further includes a first contact (the conductive via 20 located in the cell region R1) located below and electrically connected to the resistive random access memory RRAM, and a second contact (the conductive via 20 located in the capacitor region R2) located below and electrically connected to the lower electrode 24 of the dual capacitance structure DC.

In some embodiments of the present invention, the first contact (the conductive via 20 located in the cell region R1) and the second contact (the conductive via 20 located in the capacitor region R2) contain the same material, and a top surface of the first contact and a top surface of the second contact are aligned in a horizontal direction.

In some embodiments of the present invention, a width of the lower electrode 24 is equal to a width of the middle electrode 28, and a width of the upper electrode 30 is smaller than that of the middle electrode 28 in the double capacitor structure DC.

In some embodiments of the present invention, it further includes a third contact structure (refer to FIG. 7, the fourth metal layer M4 located in the cell region R1), a fourth contact (the fourth metal layer M4 located in the capacitor region R2) and a fifth contact (the conductive via V5 located in the capacitor region R2), wherein the third contact is electrically connected to a top surface of the resistive random access memory RRAM, and the fourth contact is electrically connected to the middle electrode in the double capacitor structure DC.

In some embodiments of the present invention, a top surface of the double capacitor structure DC is higher than a top surface of the resistive random access memory RRAM.

The invention also provides a method for manufacturing a semiconductor structure comprising a resistive random access memory (RRAM) and a double capacitor, which comprises providing a substrate S, wherein a cell region R1 and a capacitor region R2 are defined on the substrate S and a resistive random access memory RRAM is formed in the cell region R1, wherein the resistive random access memory RRAM comprises a variable resistance layer 26A, And forming a double capacitor structure DC in the capacitor region R2, wherein the double capacitor structure DC comprises a lower capacitor structure C1 and an upper capacitor structure C2, and the material of a first high dielectric constant layer 26B in the lower capacitor structure C1 is the same as that of the variable resistance layer 26A of the resistive random access memory RRAM.

In some embodiments of the present invention, the double capacitor structure comprises a lower electrode (first electrode layer 24), a first high dielectric constant layer 26, a middle electrode (second electrode layer 28), a second high dielectric constant layer 29 and an upper electrode (third electrode layer 30) in order from bottom to top, wherein the lower electrode 24, the first high dielectric constant layer 26 and the middle electrode 28 constitute the lower capacitor structure C1, and the middle electrode 28, the second high dielectric constant layer 29 and the upper electrode 30 constitute the upper capacitor structure C2.

In some embodiments of the present invention, a first barrier layer 27A is formed on the variable resistance layer 26A in the resistive random access memory RRAM, and a second barrier layer 27B is formed between the first high dielectric constant layer 26 and the middle electrode 28 in the double capacitor structure DC.

In some embodiments of the present invention, the materials of the first barrier layer 27A and the second barrier layer 27B are the same and formed at the same time, and the materials of the first barrier layer 27A and the second barrier layer 27B include ruthenium, iridium or platinum.

In some embodiments of the present invention, the material of the second high dielectric constant layer 29 comprises a stacked layer of zirconium dioxide and aluminum oxide (ZAZ).

In some embodiments of the present invention, a first contact (the conductive via 20 in the cell region R1) is formed below and electrically connected to the resistive random access memory RRAM, and a second contact (the conductive via 20 in the capacitor region R2) is formed below and electrically connected to the lower electrode 24 of the dual capacitance structure DC.

In some embodiments of the present invention, the first contact (the conductive via 20 located in the cell region R1) and the second contact (the conductive via 20 located in the capacitor region R2) contain the same material and are formed at the same time, and a top surface of the first contact and a top surface of the second contact are aligned in a horizontal direction.

In some embodiments of the present invention, a middle electrode material layer 28, a second high dielectric constant layer 29 and an upper electrode material layer 30 are formed in the cell region R1 and the capacitor region R2, and an etching step is performed to pattern and remove part of the middle electrode material layer 28, the second high dielectric constant layer 29 and the upper electrode material layer 30. After the above steps, the remaining middle electrode material layer 28 in the capacitor region R2 is defined as the middle electrode 28. The remaining second high dielectric constant layer 29 is defined as the second high dielectric constant layer 29, and the remaining upper electrode material layer 30 is defined as the upper electrode 30, wherein a width of the middle electrode 28 is greater than a width of the upper electrode 30 (please refer to FIGS. 2 and 3).

In some embodiments of the present invention, after the etching step, the second high dielectric constant layer 29 and the upper electrode material layer 30 in the cell region R1 are completely removed.

In some embodiments of the present invention, it further includes forming a third contact structure (refer to FIG. 7, the fourth metal layer M4 located in the cell region R1), a fourth contact (the fourth metal layer M4 located in the capacitor region R2) and a fifth contact (the conductive via V5 located in the capacitor region R2), wherein the third contact is electrically connected to a top surface of the resistive random access memory RRAM, and the fourth contact is electrically connected to the middle electrode in the double capacitor structure DC.

To sum up, the invention provides a semiconductor structure integrated with RRAM and double capacitor and a manufacturing method thereof. In which double capacitor structure is formed in the process of manufacturing RRAM, so the process steps can be saved. In addition, a contact structure can be formed at the same time in the manufacturing process to electrically connect the bottom electrode of RRAM and the bottom electrode of the double capacitor structure, so it is unnecessary to form another contact to connect the bottom electrode of the double capacitor structure in the subsequent process, which can further save the manufacturing steps. The invention effectively integrates RRAM and double capacitor under the existing manufacturing process, and provides a semiconductor integrated structure with stable structure and simple manufacturing process and a manufacturing method thereof.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure including resistive random access memory (RRAM) and double capacitor, comprising:
a substrate, a cell region and a capacitor region are defined thereon, and the capacitor region is located beside the cell region;
a resistive random access memory located in the cell region, wherein the resistive random access memory includes a variable resistance layer; and
a double capacitor structure located in the capacitor region, wherein the double capacitor structure comprises a lower capacitor structure and an upper capacitor structure, and the material of a first high dielectric constant layer in the lower capacitor structure is the same as the material of the variable resistance layer of the resistive random access memory.

2. The semiconductor structure including resistive random access memory and double capacitor according to claim 1, wherein the double capacitor structure sequentially comprises a lower electrode, the first high dielectric constant layer, a middle electrode, a second high dielectric constant layer and an upper electrode from bottom to top, wherein the lower electrode, the first high dielectric constant layer and the middle electrode constitute the lower capacitor structure, and the middle electrode, the second high dielectric constant layer and the upper electrode constitute the upper capacitor structure.

3. The semiconductor structure including resistive random access memory and double capacitor according to claim 2, further comprising a first barrier layer located on the variable resistance layer in the resistive random access memory, and a second barrier layer located between the first high dielectric constant layer and the middle electrode in the double capacitor structure.

4. The semiconductor structure including resistive random access memory and double capacitor according to claim 3, wherein the materials of the first barrier layer and the second barrier layer are the same, and the materials of the first barrier layer and the second barrier layer comprise Ru, Ir or Pt.

5. The semiconductor structure including resistive random access memory and double capacitor according to claim 2, wherein the material of the second high dielectric constant layer comprises a stacked layer of zirconium dioxide and aluminum oxide (ZAZ).

6. The semiconductor structure including resistive random access memory and double capacitor according to claim 2, further comprising a first contact located below the resistive random access memory and electrically connected to the resistive random access memory, and a second contact located below the double capacitor structure and electrically connected to the lower electrode of the double capacitor structure.

7. The semiconductor structure according to claim 6, wherein the first contact and the second contact comprise the same material, and a top surface of the first contact and a top surface of the second contact are aligned in a horizontal direction.

8. The semiconductor structure including resistive random access memory and double capacitor according to claim 2, wherein in the double capacitor structure, a width of the lower electrode is equal to a width of the middle electrode, and a width of the upper electrode is smaller than the width of the middle electrode.

9. The semiconductor structure including resistive random access memory and double capacitor according to claim 2, further comprising a third contact structure, a fourth contact and a fifth contact, wherein the third contact is electrically connected to a top surface of the resistive random access memory, the fourth step is electrically connected to the middle electrode in the double capacitor structure, and the fifth contact is electrically connected to the upper electrode in the double capacitor structure.

10. The semiconductor structure including resistive random access memory and double capacitor according to claim 1, wherein a top surface of the double capacitor structure is higher than a top surface of the resistive random access memory.

11. A manufacturing method of a semiconductor structure including a resistive random access memory (RRAM) and a double capacitor, comprising:
providing a substrate, wherein a cell region and a capacitor region are defined on the substrate and located beside the cell region;
forming a resistive random access memory located in the cell region, wherein the resistive random access memory comprises a variable resistance layer; and
forming a double capacitor structure in the capacitor region, wherein the double capacitor structure comprises a lower capacitor structure and an upper capacitor structure, and the material of a first high dielectric constant layer in the lower capacitor structure is the same as the material of the variable resistance layer of the resistive random access memory.

12. The method for manufacturing a semiconductor structure including resistive random access memory and double capacitor according to claim 11, wherein the double capacitor structure comprises a lower electrode, the first high dielectric constant layer, a middle electrode, a second high dielectric constant layer and an upper electrode in order from bottom to top, wherein the lower electrode, the first high dielectric constant layer and the middle electrode constitute the lower capacitor structure, and the middle electrode, the second high dielectric constant layer and the upper electrode constitute the upper capacitor structure.

13. The method for manufacturing a semiconductor structure including resistive random access memory and double capacitor according to claim 12, further comprising forming a first barrier layer on the variable resistance layer in the resistive random access memory and forming a second barrier layer between the first high dielectric constant layer and the middle electrode in the double capacitor structure.

14. The method for manufacturing a semiconductor structure including resistive random access memory and double capacitor according to claim 13, wherein the first barrier layer and the second barrier layer are made of the same material and are formed at the same time, wherein the materials of the first barrier layer and the second barrier layer comprise Ru, Ir or Pt.

15. The method for manufacturing a semiconductor structure including resistive random access memory and double capacitor according to claim 12, wherein the material of the second high dielectric constant layer comprises a stacked layer of zirconium dioxide and aluminum oxide (ZAZ).

16. The method for manufacturing a semiconductor structure including resistive random access memory and double capacitor according to claim 12, further comprising forming a first contact below the resistive random access memory and electrically connecting the resistive random access memory, and forming a second contact below the double capacitor structure and electrically connecting the lower electrode.

17. The method for manufacturing a semiconductor structure including resistive random access memory and double capacitor according to claim 16, wherein the first contact and the second contact are made of the same material and are formed at the same time, and a top surface of the first contact and a top surface of the second contact are aligned in a horizontal direction.

18. The method for manufacturing a semiconductor structure including resistive random access memory and double capacitor according to claim 12, further comprising:
forming a middle electrode material layer, a second high dielectric constant layer and an upper electrode material layer in the cell region and the capacitor region; and
performing an etching step to pattern and remove part of the middle electrode material layer, the second high dielectric constant layer and the upper electrode material layer, after the above steps, the remaining middle electrode material layer located in the capacitor region is defined as the middle electrode, the remaining second high dielectric constant layer is defined as the second high dielectric constant layer, and the remaining upper electrode material layer is defined as the upper electrode, wherein a width of the middle electrode is greater than a width of the upper electrode.

19. The method for manufacturing a semiconductor structure including resistive random access memory and double capacitor according to claim 18, wherein after the etching step, the second high dielectric constant layer and the upper electrode material layer in the cell region are completely removed.

20. The method for manufacturing a semiconductor structure including resistive random access memory and double capacitor according to claim 12, further comprising forming a third contact, a fourth contact and a fifth contact, wherein the third contact is electrically connected to a top surface of the resistive random access memory, the fourth contact is electrically connected to the middle electrode in the double capacitor structure, and the fifth contact is electrically connected to the upper electrode in the double capacitor structure.
